(19) United States
(12) Patent Application Publication
(10) Pub. No.: US 2003/0124813 A1
(43) Pub. Date: Jul. 3, 2003

(54) Method of fabricating shallow trench isolation

(76) Inventor: Shyh-Dar Lee, Hsinchu Hsien (TW)

Correspondence Address: BIRCH STEWART KOLASCH & BIRCH, PO BOX 747, FALLS CHURCH, VA, 22040-0747, US

(21) Appl. No.: 10/095,696

(22) Filed: Mar. 13, 2002

(30) Foreign Application Priority Data
Dec. 31, 2001 (TW) 90133414

(51) Int. Cl. H01L 21/76

(52) U.S. Cl. 438/400; 438/424

(57) ABSTRACT

A method of fabricating a shallow trench isolation. The oxide layer is treated by a nitrogen-based compound. After treatment, the oxide layer plays not only the role of the etching mask during shallow trench isolation formation, but also of the stop layer during chemical mechanical polishing. Therefore, the selectivity of the chemical mechanical polishing is enhanced.

### BACKGROUND OF THE INVENTION

1. Field of the Invention

The present invention relates in general to fabricating a shallow trench isolation, and particularly to fabricating a shallow trench isolation for enhancing the selectivity between the isolation and the stop layer during chemical mechanical polishing.

2. Description of the Related Art

As methods of fabricating semiconductor integrated circuits (IC) continually improve, the number of devices that may be introduced into a single semiconductor chip has increased, while the size of each device has decreased. Millions of devices may now be fabricated on a single chip. Particularly in such high-density semiconductor devices, individual devices must be properly isolated in order to maintain acceptable performance, For example, improper isolation between transistors may cause additional leakage current, resulting in poor noise margin, threshold voltage shift, cross-talk and circuit latchup.

In metal-oxide semiconductor (MOS) technology, isolation is generally achieved by forming isolation regions between neighboring active areas. Typically, an isolation area is formed by ion-doping a channel stop of polarity opposite to the source electrode and the drain electrode of the IC device, and growing a thick oxide, often referred to as field oxide (FOX). The channel stop and the FOX cause the threshold voltage in the isolation area to be much higher than those in the neighboring active regions, thereby ensuring that surface inversion does not occur under the FOX area.

One method known in the art for laterally isolating IC devices is known as Local Oxidation of Silicon (LOCOS). A LOCOS structure is typically formed by using a patterned silicon nitride layer together with a pad oxide to mask the active areas, followed by ion-implantation in the isolation region. Thereafter, a thick field oxide is grown locally in the isolation region. The LOCOS structure possesses some inherent drawbacks, such as lateral oxidation of the silicon underneath the silicon nitride mask, which makes the edge of the field oxide region resemble the shape of a bird's beak. The bird's beak shape causes unacceptably large encroachment of the field oxide into the device active regions.

Shallow trench isolation (STI) technology was created to overcome the disadvantages of the LOCOS technique.

In FIG. 1A, a pad oxide layer 4 and a silicon nitride layer 6 are sequentially formed on a silicon substrate 2. The pad oxide layer 4 is usually formed by thermal oxidation, and the silicon nitride layer 6 is usually formed by chemical vapor deposition.

In FIG. 1B, a photographic and etching process is performed to pattern the silicon nitride 6 and the pad oxide layer 4, and to then form trenches 10 in the substrate 2.

In FIG. 1C, a liner oxide layer 12 is typically formed by thermal oxidation on the side-wall and the bottom of the trenches 10.

Next, a chemical vapor deposition process is performed using ozone (O₃) and tera-ethyl-ortho-silicate (TEOS) as precursors to form an isolated layer 14 filling the trenches 10 and covering the silicon nitride 6, as shown in FIG. 1D.

In FIG. 1E, the isolated layer 14 is subjected to planarization, such as chemical mechanical polishing, to form planarized shallow trench isolations 14a. Finally, a wet etching is preferably performed to remove the silicon nitride layer 6 and the pad oxide layer 4, as shown in FIG. 1F.

However, in the traditional process mentioned above, the silicon nitride is used as the etching mask, resulting in defects forming in the semiconductor substrate by introduced stress during etching. Using oxide as the etching mask is thus proposed to avoid the above problem. Another problem accompanying use of oxide as the etching mask during a shallow trench isolation production involves the poor selectivity of chemical mechanical polishing between the oxide mask as a stop layer and the oxide isolation

### SUMMARY OF THE INVENTION

To solve above problem, it is an object of the present invention to provide a shallow trench isolation formation method to enhance the selectivity between the isolation and the stop layer during chemical mechanical polishing.

The object of the present invention is to provide a method of fabricating a shallow trench isolation without defects appearing in the substrate.

The method comprises the following steps. A semiconductor substrate is provided. A first mask layer is formed on the substrate. The first mask layer is treated with a thermal treatment to form a second mask layer. The second mask layer is then patterned to act as an etching mask. The substrate is subjected to etching to form trenches therein. An isolated layer is formed to fill the trenches as well as cover the surface of the patterned second mask layer. The isolated layer is planarized until the top of the second mask layer is exposed by chemical mechanical polishing. Finally, the second mask layer is removed.

In accordance with this invention, the first mask layer comprises silicon dioxide formed by chemical vapor deposition. 5 As well, gases comprising a nitrogen-based compound are introduced during the thermal treatment. The isolated layer comprises oxide formed by high density plasma chemical vapor deposition.

With the above flow, the shallow trench isolation is 10 fabricated, and the selectivity of the isolation and the mask layer as a step layer of chemical mechanical polishing is enhanced.

### BRIEF DESCRIPTION OF THE DRAWINGS

The above and other objects, features, and advantages of the present invention will become apparent from the following detailed description of preferred embodiments of the invention explained with reference to the accompanying drawings, in which:

FIGS. 1A-1F are schematic cross-section illustrating steps for fabricating a shallow trench according to the prior art.

FIGS. 2A-2H are schematic cross-section illustrating steps for fabricating a shallow trench according to the preferred embodiment of the invention.

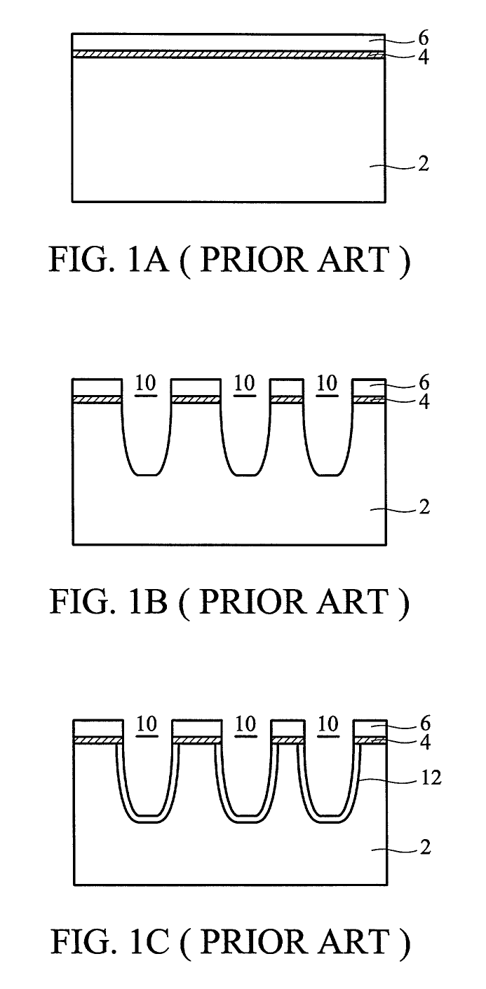

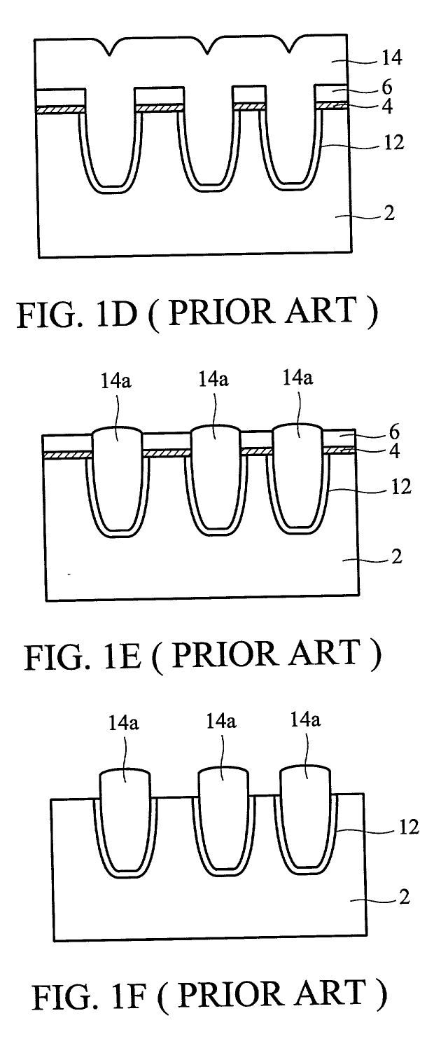

### DETAILED DESCRIPTION OF THE PREFERRED EMBODIMENT

There will now be described an embodiment of this invention with reference to the accompanying drawings.

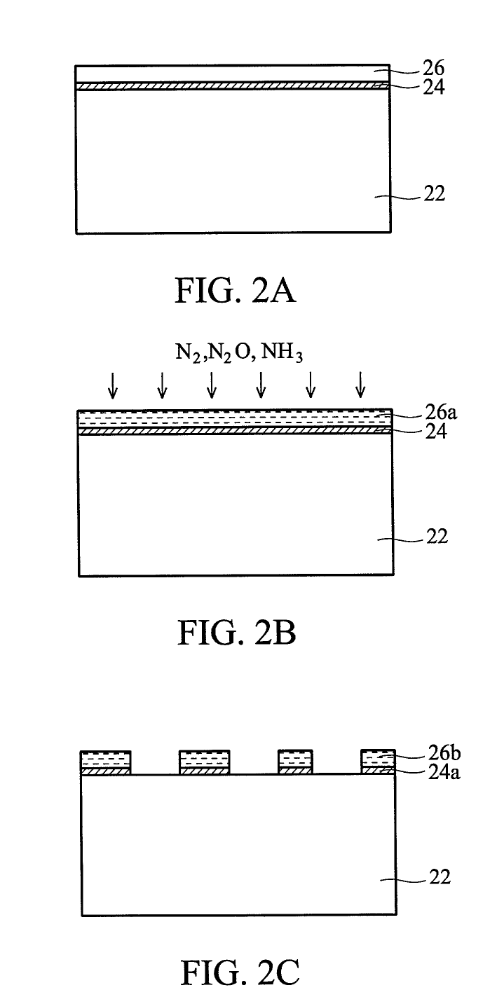

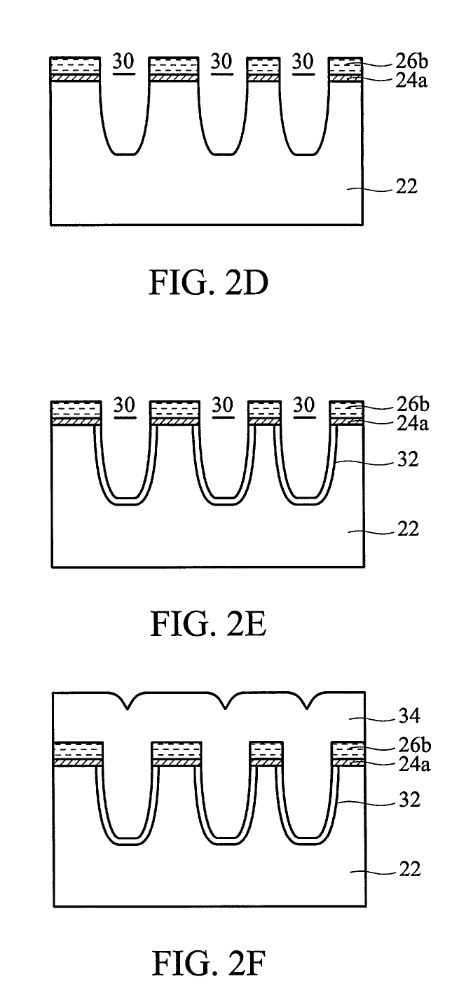

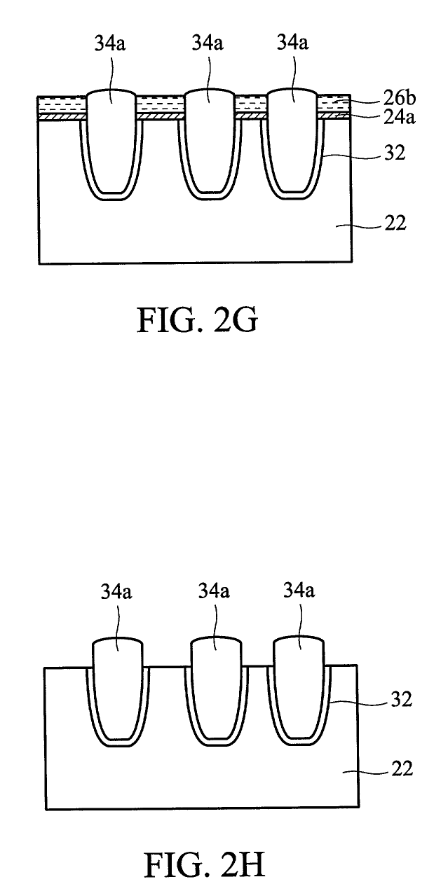

As shown in FIG. 2A, on a semiconductor substrate 22, a pad oxide layer 24 and an oxide layer 26 are sequentially formed. The pad oxide layer 24 is usually formed by thermal oxidation. The material of the oxide layer 26 is preferably silicon dioxide that is formed by well known atmospheric and low pressure chemical vapor deposition (LPCVD).

Next, the oxide layer 26 is subject to plasma implantation at a temperature between about 300 and 500° C. and the processing gases comprise a nitrogen-based compound including N₂O, NH₃, and N₂, diffusing into the oxide layer 26 to form a nitrogen-based and oxygen-based compound, such as SiOₓN_{y}, as a mask layer 26a, as shown in FIG. 2B. The fluxing of nitrogen is preferably about 300 to 500 c.c./min, and the fluxing of ammonia gas is preferably about 200 to 400 c.c./min.

As shown in FIG. 2D, the mask layer 26a is patterned to act as an etching mask 26b. The pad oxide layer 24 and the substrate 22 are then etched to form trenches 30 in the substrate 22, as shown in 2D.

In FIG. 2E, a liner layer 32 can be formed on the bottom and the side-walls of the trenches to revamp the defects produced during formation of the trenches 30 by thermal oxidation at the temperature about 1000° C.

Next, an isolated layer 34 is preferably formed to fill the trenches 30 as well as cover the surface of the patterned mask layer 26b by high density plasma chemical vapor deposition. The substrate 22 is prevented from damage during the high density plasma chemical vapor deposition process by re-formed liner oxide layer 32, as shown in FIG. 2F.

Then, the isolated layer 34 is subjected to planarization by chemical mechanical polishing until the top of the patterned mask layer 26b is exposed to form shallow trench isolations 34a, as shown in FIG. 2G.

Finally, the patterned mask layer 26b and the pad oxide layer 24 are preferably removed by wet etching, as shown in FIG. 2H.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method of fabricating a shallow trench isolation, comprising:
providing a substrate;
forming a first mask layer on the substrate;
performing a thermal treatment to the first mask layer to form a second mask layer;
patterning the second mask layer to act as an etching mask;
etching the substrate to form trenches;
forming a isolated layer to fill the trenches as well as cover the surface of the patterned second mask layer;
planarizing the isolated layer until the top of the second mask layer is exposed; and
removing the second mask layer.

2. The method as claimed in claim 1, wherein the first mask layer comprises silicon dioxide.

3. The method as claimed in claim 1, wherein the silicon dioxide layer is formed by chemical vapor deposition.

4. The method as claimed in claim 1, wherein the thermal treatment is performed at 300-500° C.

5. The method as claimed in claim 1, wherein gases are introduced during the thermal treatment.

6. The method as claimed in claim 5, wherein the gases comprise a nitrogen-based compound.

7. The method as claimed in claim 1, wherein the isolated layer comprises oxide.

8. The method as claimed in claim 1, wherein the oxide layer is formed by high density plasma chemical vapor deposition.

9. The method as claimed in claim 8, further comprising before forming the isolated layer, forming a liner oxide on the side-walls and the bottom of the trenches.

10. The method as claimed in claim 9, wherein the liner oxide is formed by thermal oxidation.

11. The method as claimed in claim 1, wherein the step of planarizing the isolated layer comprises chemical mechanical polishing.

12. A method of fabricating a shallow trench isolation, comprising:
providing a substrate;
forming a pad oxide layer and an oxide layer on the substrate sequentially;
introducing gases comprising a nitrogen-based compound to diffuse into the oxide layer;
patterning the oxide layer to act as an etching mask;
etching the substrate to form trenches;
forming an isolated layer to fill the trenches as well as cover the surface of the patterned oxide layer;
planarizing the isolated layer until the top of the patterned oxide layer is exposed; and
removing the patterned oxide layer and the pad oxide layer.

13. The method as claimed in claim 12, wherein the oxide is formed by chemical vapor deposition.

14. The method as claimed in claim 12, wherein the pad oxide is formed by thermal oxidation.

15. The method as claimed in claim 12, wherein the gases are introduced at 300-500° C.

16. The method as claimed in claim 12, wherein the gases comprise nitrogen (N2), (NH3), (N2O).

17. The method as claimed in claim 12, wherein the isolated layer comprises an oxide.

18. The method as claimed in claim 17, wherein the oxide layer is formed by high density plasma chemical vapor deposition.

19. The method as claimed in claim 18, further comprising before forming the oxide layer, forming a liner oxide layer on the side-walls and the bottom of the trenches.

20. The method as claimed in claim 19, wherein the liner oxide is formed by thermal oxidation.
